(19) United States
(12) Patent Application Publication
(10) Pub. No.: US 2025/0164545 A1
(43) Pub. Date: May 22, 2025

(54) MEASUREMENT METHOD OF FLATBAND VOLTAGE OF POWER SEMICONDUCTOR MODULE

(71) Applicant: MITSUBISHI ELECTRIC CORPORATION, TOKYO (JP)

(72) Inventors: JULIO BRANDELERO, RENNES Cedex 7 (FR); NICOLAS DEGRENNE, RENNES Cedex 7 (FR)

(73) Assignee: MITSUBISHI ELECTRIC CORPORATION, TOKYO (JP)

(21) Appl. No.: 18/839,671

(22) PCT Filed: Jul. 27, 2022
(86) PCT No.: PCT/JP2022/029724

§ 371 Date: Aug. 19, 2024

(30) Foreign Application Priority Data
Mar. 23, 2022 (EP) 22305350.5

(51) Int. Cl. G01R 31/26; G01R 19/00

(52) U.S. Cl. CPC G01R 31/2621; G01R 19/0084; G01R 31/2608

(57) ABSTRACT

A measurement method of a flatband voltage of a power semiconductor module during operational service, said method comprising:
a. applying a bias voltage to said module such that said module switches between off-state and on-state;
b. triggering a gate current I_{g} injection from a current source to a gate of the module when an initial gate-emitter/source voltage is equal to a flatband voltage V_{fb,h} of the module;
c. measuring the voltage V_{g} across the current source;
d. extracting of a flatband voltage V_{fb,h+1} from the said measured voltage V_{g} across the current source
e. stopping said gate current I_{g} injection
   when the absolute difference between the gate emitter/source voltage and the flatband voltage V_{fb,h} becomes superior to a predefined limit; or
   when the gate current I_{g} injection duration tᵢₙⱼ exceeds a predetermined duration tₘₐₓ;
f. saving the extracted flatband voltage V_{fb,h+1} value.

### TECHNICAL FIELD

This disclosure pertains to the field of monitoring of power semiconductors during operational service.

### BACKGROUND ART

To monitor and estimate the threshold voltage shift during the life of a semiconductor is a classical activity to evaluate the Bias Temperature Instability (BTI) of such components. It is known to monitor BTI in a power semiconductor Metal-Oxide-Semiconductor type (MOS) or in paralleled connected power semiconductor MOS types or in a Metal-Insulator-Semiconductor type (MIS) or in paralleled connected power semiconductor MIS types, especially in power semiconductors devices/modules, like multichip power modules, for protection, condition and health monitoring.

Many BTI estimations methods are known but are not entirely satisfactory. It is possible to have static measurements to determine the threshold voltage shift. But it leads to underestimations of the threshold voltage value because of the recovery of the charge trapping between the end of the bias and the measurement. In such case, the threshold voltage of the power semiconductor can be measured when the converter is in idle state. It is possible to measure the transitory bias instability by making the time between the stress and the threshold voltage measurement inferior to 100 ms. We can measure the shoot-through current and charge during switching transients. We can use the changing trend of a device's voltage, current, temperature with its degradation within accelerated aging tests for data collection and on-line degradation monitoring. Due to the settling time imposed by the monitoring system, accurate measurements require low switching frequency and high modulation indexes when monitoring. In this aim, a DPWM strategy (Digital Pulse Width Modulator) is proposed to monitor a device during a certain time where the power switch it is not switching, and hence, increase the accuracy of the measurements. All these known methods imply to stop the normal operation and/or stop the switching of the modules and/or have biases in certain situations.

### SUMMARY OF INVENTION

This disclosure improves the situation.

It is proposed a measurement method of a flatband voltage of a power semiconductor module comprising at least one semiconductor element among a Metal-Oxide-Semiconductor element and a Metal-Insulator Semiconductor element during operational service. The method comprises:
a. applying a bias voltage to said module such that said module switches from an off-state to an on-state, or from an on-state to an off-state;
b. triggering a gate current I_{g} injection from a current source to a gate of the module when an initial gate-emitter/source voltage is equal to a flatband voltage V_{fb,h} of the module within +/−5V;
c. measuring the voltage V_{g} across the current source;
d. extracting of a flatband voltage V_{fb,h+1} from the said measured voltage V_{g} across the current source
e. stopping said gate current I_{g} injection
   when the absolute difference between the gate emitter/source voltage and the flatband voltage V_{fb},h becomes superior to a predefined limit; or
   when the gate voltage I_{g} injection duration tᵢₙⱼ exceeds a predetermined duration tₘₐₓ;
f. saving the extracted flatband voltage V_{fb,h+1} value.

In another aspect, it is proposed a power semiconductor module comprising a single Metal-Oxide-Semiconductor or a single Metal-Insulator-Semiconductor element or a set of Metal-Oxide-Semiconductor elements or a set of Metal-Insulator-Semiconductor elements or a combination of Metal-Oxide-Semiconductor elements and Metal-Insulator-Semiconductor elements, said module being arranged to implement the method as defined here.

In another aspect, it is proposed a computer software comprising instructions to implement the method as defined here when the software is executed by a processor. In another aspect, it is proposed a computer-readable non-transient recording medium on which a software is registered to implement the method as defined here when the software is executed by a processor.

The following features, can be optionally implemented, separately or in combination one with the others.

The method further comprises:
measuring a capacity Cₘₑₐₛ of the at least one semiconductor element, and wherein
   the extracted flatband voltage V_{fb,h+1} is the measured voltage V_{ig} across the current source triggered when a transition between a constant Cₘₑₐₛ to a variable Cₘₑₐₛ is detected from the capacity measurement.

The sign of the injected gate current I_{g} depends on the ON/OFF state of the semiconductor element.

The injected gate current I_{g} is negative and
the gate current I_{g} injection is stopped when the measured voltage V_{ig} achieves a predetermined negative voltage,
the temporal derivative voltage dV_{ig}/dt is calculated and stored in such a way that it can be used as an input parameter to reiterate the method.

If the calculated temporal derivative voltage dV_{ig}/dt does not drop more than a predetermined relative value, the method is then reiterated with a positive injected gate current Ig.

The gate current I_{g} injection triggering is made:
after a time tₚ of the switching-off of the semiconductor element, and the extraction of a positive gate bias flatband voltage V_{fb,h+1}; and/or
a time tₙ before the switching-on of the semiconductor element.

The flatband voltage V_{fb,h+1} is extracted from the said measured voltage V_{ig} across the current source at an instant when a gate current I_{g} injection is triggered in response to a condition on a second temporal derivative d²V_{ig}/dt² of a measured voltage V_{ig}.

The method further comprises:
a bus voltage measurement before the flatband voltage V_{fb,h+1} extraction, and
a measurement of the duration of the ON state and/or of the duration of the OFF state before the flatband voltage V_{fb,h+1} extraction.

The series of operations is reiterated at least one time such that to output a flatband evolution along time.

Other features, details and advantages will be shown in the following detailed description and on the figures.

### BRIEF DESCRIPTION OF DRAWINGS

FIG. 1 is a schematical representation of a physical phenomenon.

FIG. 2 is a graphic view of the oxide Capacity in function of the Gate-to-Source Voltage V_{GS} of semiconductor modules having different ages.

FIG. 3 is a graphic view of the ratio of the Capacity of the oxide part on the maximum of said capacity in function of the Gate-to-Source Voltage V_{GS} of a semiconductor module in different ages stages.

FIG. 4 is a circuitry according to an embodiment.

FIG. 5 is a circuitry according to an embodiment.

FIG. 6 is a graphic view of some data obtained during an embodiment.

FIG. 7 is a graphic view of some data obtained during an embodiment.

FIG. 8 is a graphic view of some data obtained during an embodiment.

FIG. 9 is an example of an equivalent circuit used to obtain some data according to an embodiment.

FIG. 10 is a combination of various graphic views obtained in a first situation.

FIG. 11 is a combination of various graphic views obtained in a second situation.

FIG. 12 is a graphic view of some data obtained during according to an embodiment.

FIG. 13 is a graphic view of some data obtained during according to an embodiment.

FIG. 14 is schematic representation of the evolution of some index during the lifetime of a power semiconductor element.

### DESCRIPTION OF EMBODIMENTS

### Main Problems to Solve

Bias temperature instability (BTI) is a reliability issue concerning the insulated gate power modules, such Metal-Oxide-Semiconductor-Field-Effect-Transistors (MOSFET), Insulated-Gate-Bipolar-Transistors (IGBT) and High-Electron-Mobility-Transistors (HEMT). In the SiC power semiconductor elements, this phenomenon is much more problematic during the device lifetime than in Si power semiconductor elements (approximately ten times higher), due to the reduced band offsets between the gate oxide and the power semiconductor occurrence and the carbon atoms degrading the atomically smooth Si/SiO₂ interface. The charge trapping also concerns the reliability in GaN HEMTs devices, due to the gate stack structure complexity.

The charge trapping can be a permanent or a transitory phenom which the main consequences of this reliability issue are:
i/ “On-state resistance RDS(on) increase”—leading to an over-loss dissipation on the devices/modules and an over-temperature during the power semiconductor elements operation which can be catastrophic for the integrity of the materials;
ii/ “Body diode threshold voltage”—leading to an over-loss dissipation on the element and an over-temperature during the power semiconductor operation; iii/ “Off-state blocking leakage IDSS(off)”—that will generate extra losses on the element and can also lead to a catastrophic failure;
iv/ “Shoot-Through Currents”—given the change in the ON and OFF time delay. The initial dead time from power semiconductor cannot be enough to switch the series devices safely and create catastrophic short circuit failure.

In each previous concerns, the extra losses generated by the deterioration will increase the temperature of the power semiconductor which accelerates the degradation. In RF domain, the MOSFETs linearity degradation due to stress is also concerned.

Identifying the gate oxide degradation under on-line operation of the power semiconductor is a key parameter to assess the reliability of such devices: from a test and safety assessment point of view (including standards) and dispatch/maintenance of the power converter.

### {Theory}

The flatband voltage V_{fb} is a voltage that when applied to a semiconductor element generates a flat energy band in the semiconductor and is determined by the following equation [Math. 1].

$${V}_{fb} = {Φ}_{MS} - \frac{{Q}_{ox}}{{C}_{ox}} - \frac{1}{{ε}_{ox}} {\int }_{0}^{{t}_{ox}} {ρ}_{ox} ( x ) \cdot x \cdot dx \qquad [ Math . 1 ]$$

Φ_{MS} is the work function difference between the gate metal material and the semiconductor material. Cₒₓ is the thin oxide capacitance. Qₒₓ is the total effective charge in the oxide. The last term of [Math. 1] is due to the charge density in the oxide.

Ones can note that the flatband voltage is affected by the presence of charges on the oxide-semiconductor interface. The charges presented in this interface are sensitive to the electric field formed on the channel. As the positive gate voltages generate a positive electrical field conducting to a negative charge accumulation on the oxide, the flatband voltage increases by the equation [Math. 1]. In an opposite way, as the negative gate voltages generate a negative electrical field conducting to a positive charge accumulation on the oxide, the flatband voltage decreases by the equation [Math. 1]. This phenomenon is called Bias Temperature Instability, or BTI. For a positive electrical field, it is called Positive Temperature Bias instability (PBTI). And for a negative electrical field, this is called Negative Temperature Bias Instability (NBTI).

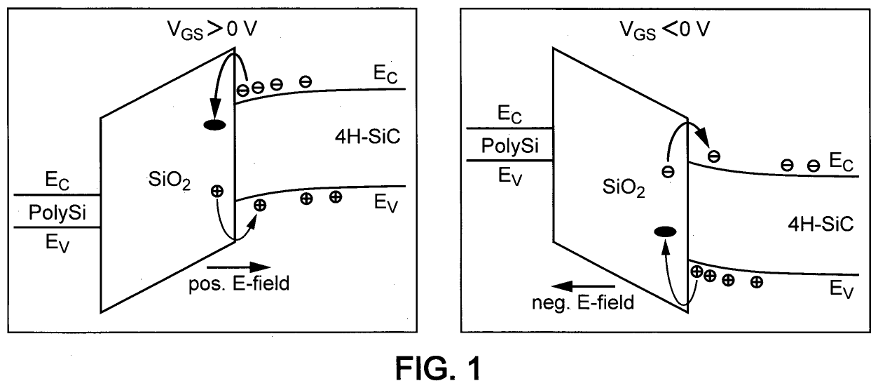

FIG. 1 is based on a figure published in the following paper: X. Zhong and e. al, “Bias Temperature Instability of Silicon Carbide Power MOSFET Under AC Gate Stresses” IEEE Transactions on Power Electronics, vol. 37, no. 2, pp. 1998-2008, February 2022, doi: 10.1109/TPEL.2021.3105272. FIG. 1 illustrates the above-described phenomena, the left part corresponding to a situation wherein the gate-source voltage V_{GS} is superior to 0 V, while the right part corresponds to a situation wherein the gate-source voltage V_{GS} is inferior to 0 V.

Despite the efforts during design to avoid the incorporation of charges on the oxide, during the lifetime of the power semiconductor element, positive or negative electrical fields will trap charges on the gate oxide. This phenomenon is hardly avoided in the case of SiC or GaN semiconductors materials where more interface states and fixed oxide charge appear after a high electric field application. The trapped charge is also significantly increased with a high switching frequency and/or by a hot device temperature.

One of the main consequences of the gate oxide deterioration is the evolution on the threshold voltage Vₜₕ that is described as per following equations [Math. 2] and [Math. 3].

$${V}_{th} = {V}_{fb} + 2 {Φ}_{f} + \frac{\sqrt{4 \cdot {ε}_{s} \cdot q \cdot {N}_{a} \cdot {Φ}_{f}}}{{C}_{ox}} \qquad [ Math . 2 ]$$

$${Φ}_{f} = \frac{kT}{q} ln \frac{{N}_{a}}{ni} \qquad [ Math . 3 ]$$

Nₐ is the acceptor density in the substrate. εₛ is the semiconductor dielectric constant. k is the Boltzmanns constant. T is the temperature. ni is the intrinsic carrier concentration. Cₒₓ is the oxide capacitor value.

As the gate and the substrate doping and the oxide thickness are not affected by the voltage bias stress, the noticeable change on the threshold voltage Vₜₕ is related to the changes on the oxide charges and then can be monitored only by the measurement of the flatband voltage V_{fb} as per following equation [Math. 4].

$$Δ {V}_{th} = {V}_{th ( fresh )} - {V}_{th ( stress )} = {V}_{fb ( fresh )} - {V}_{fb ( stress )} \qquad [ Math . 4 ]$$

In order to measure the flatband voltage V_{fb}, the variation of the injected gate charge dQ_{g} by the variation of the gate voltage dV_{g} can be applied as the following equation [Math. 5], for V_{g}<Vₜₕ.

$$C = \frac{{dQ}_{g}}{{dV}_{g}} = min ( \frac{1}{\sqrt{\frac{1}{{C}_{ox}^{2}} + \frac{2 ( {V}_{g} - {V}_{fb} )}{{ε}_{s} \cdot q \cdot {N}_{a}}}} , {C}_{ox} ) \qquad [ Math . 5 ]$$

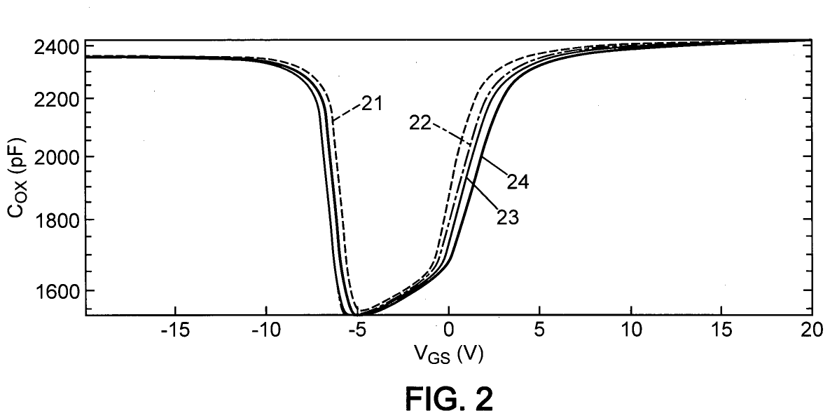

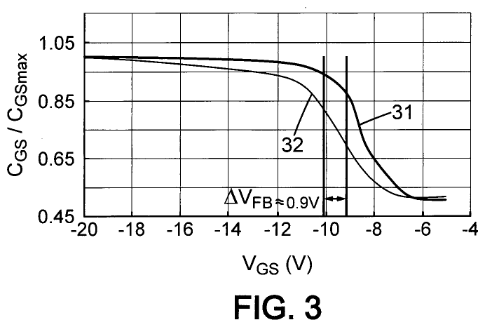

This is given by the fact that for a V_{g} superior to the flatband voltage V_{fb}, the equivalent capacitor C is the series connection between the oxide capacitor and the depletion capacitor. When the gate voltage V_{g} is inferior to the flatband voltage V_{fb}, the capacitor C is only related to the gate oxide capacitor. Thus, the transition between a constant C to a variable C value on the gate voltage can be used as an indicator of the flatband voltage V_{fb}. This is illustrated by FIG. 2 and FIG. 3.

FIG. 2 is based on a figure published in the following paper: M. Farhadi, F. Yang, S. Pu, B. T. Vankayalapati and B. Akin, “Temperature-Independent Gate-Oxide Degradation Monitoring of SiC MOSFETs Based on Junction Capacitances” in IEEE Transactions on Power Electronics, vol. 36, no. 7, pp. 8308-8324, July 2021, do. Each curve represents the oxide capacity in function of the Gate-to-Source voltage V_{GS}. Each curve corresponds to a situation with a known age of the power semiconductor element:
curve 21: 10 hours
curve 22: 100 hours
curve 23: 200 hours
curve 24: 300 hours.

As we can see on FIG. 2, there is a sensitive area to aging, here approximately between −10 and −5 Volts that comprises the flatband voltage: The oxide capacity is highly dependent from the age of the component.

FIG. 3 is based on a figure published in the following paper: S. Mbarek, F. Fouquet, P. Dherbecourt, M. Masmoudi and O. Latry, “Gate oxide degradation of SiC MOSFET under short-circuit aging tests” Microelectronics Reliability, vol. 64, no. https://doi.org/10.1016/j.microrel.2016.07.132., pp. 415-418, 2016. Each curve represents the ratio of the gate-source capacity C_{GS} on its maximum C_{GSmax} in function of the Gate-to-Source voltage V_{GS}. The curve 31 corresponding to measures made before aging of the component while the curve 32 corresponds to measures made after aging at 250 μs of the same component. The difference between the two corresponding flatband voltages V_{fb} is superimposed on the curves 31, 32, here with a value of approximately 0.9 Volts (ΔV_{f}).

### Description of Embodiments

In the following, power semiconductor modules 1 are assembly comprising a single Metal-Oxide-Semiconductor (MOS) or a single Metal-Insulator-Semiconductor (MIS) element or a set of combined MOS and/or MIS elements. Even if the module 1 comprises a plurality of MOS or MIS elements, there are considered as single one in the following: there is a common gate G, a common source S and a common drain D. For this reason, it is referred to a single gate, a single source and a single drain in the following without distinction of embodiments with a single one or a plurality of MOS elements. The word “power” is used in its general meaning of the technical field of energy conversion (power electronics).

An aim of the following method is to estimate the Bias Temperature Instability (BTI) of a power semiconductor module 1 in order to detect a deterioration of the gate oxide. Here, a method is proposed that can be used in operational conditions, typically not only on a test bench but when the module is integrated and interconnected in its operational and industrial environment.

The method comprises the following operations:
a. applying a bias voltage to the module 1 such that said module switches from an off-state to an on-state, or from an on-state to an off-state;
b. triggering a gate current I_{g} injection from a current source 44 to a gate of the module when an initial gate-emitter/source voltage is equal to a flatband voltage V_{fb,h} of the module within +/−5V, or less for example within +/−4V;
c. measuring the voltage V_{g} across the current source;
d. extracting of a flatband voltage V_{fb,h+1} from the said measured voltage V_{g} across the current source
e. stopping said gate current I_{g} injection when the absolute difference between the gate emitter/source voltage and the flatband voltage V_{fb,h} becomes superior to a predefined limit or when the gate voltage I_{g} injection duration tᵢₙⱼ exceeds a predetermined duration tₘₐₓ;
f. saving the extracted flatband voltage V_{fb,h+1} value.

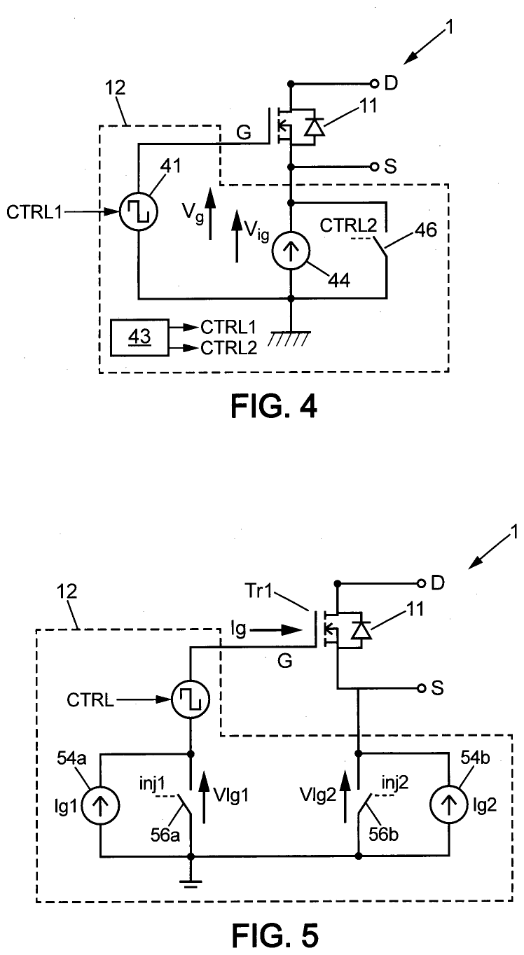

In an embodiment shown on FIG. 4, the module 1 comprises a Metal-Oxide-Semiconductor (MOS) element or a Metal-Insulate-Semiconductor (MIS) element (“semiconductor element 11” or “transistor” hereinafter) and a control circuitry 12. The control circuitry 12 includes a gate driver voltage source 41 that controls the gate G of said semiconductor element between ON and OFF states following a control signal CTRL1, and a current source 44. The gate driver voltage value is referenced V_{g}. In the example, the (total) voltage values of the gate G during ON state is referenced V_{cc} and is around 15V (classically between 10V and 20V) and the voltage values of the gate G during OFF state is referenced Vₑₑ and is around −5V (classically between −20V and 0V). The instants of the transition between the OFF and ON states are determined by the control signal CTRL1 sent by a controller 43 that alternates within a switching period. In some embodiments, the said controller 43 is a component of the module 1. In other embodiments, the said controller 43 is external to the module 1. The triggering of a gate current I_{g} injection (operation b) is executed by the controller 43.

The current source 44 of the gate current I_{g} injection is a DC current source. In the example, the current source has values from −100 mA to 100 mA. The module 1 comprises means able to control the injections of the currents on the gate G through a control signal CTRL2. In the example, such means comprises a switch 46. In various embodiments, such means can have other structure adapted to the architecture of the control circuitry 12, for example a set of parallel or series switches.

The voltage V_{ig} across the current source 44 is representative on the gate-source voltage V_{gs} of the semiconductor element 11, as V_{ig}=V_{g}−V_{gs} or V_{ig}=Vₑₑ−V_{gs}. The voltage V_{ig} across the current source 44 is measured (operation c), for example continuously. The flatband voltage V_{fb} can be extracted from the variation of the injected gate charge, in this implementation example, the direct current I_{g}, by the variation of the gate voltage V_{ig} on time t, as V_{g} is constant during the measurement time t (equals to Vₑₑ) according to the following [Math. 6] and [Math. 7].

$$\frac{{dV}_{gs}}{dt} = \frac{{dV}_{ig}}{dt} \qquad [ Math . 6 ]$$

$${C}_{meas} = \frac{{I}_{g}}{{dV}_{ig} / dt} \qquad [ Math . 7 ]$$

The voltage V_{ig} transition across the current source 44, between a constant measured capacity Cₘₑₐₛ to a variable measured capacity Cₘₑₐₛ value, is an indicator of the flatband voltage V_{fb}. In other words, the value of the voltage V_{ig}(t) at the instant t when the measured capacity Cₘₑₐₛ becomes dependent can be used to estimate the value of the updated flatband voltage V_{fb,h+1}. For such implementation method, a stable derivative of measured capacity Cₘₑₐₛ trigger a sampling of the voltage Vₑₑ−V_{ig} as the estimated flatband voltage V_{fb,h+1} (operation d).

In some embodiments, optional supplementary conditions can be imposed in order to ensure a good reliability of the estimation. For example, a minimum frequency of the AC signal and/or a minimum sampling rate can be set.

The current injection I_{g} is stopped (operation e) when at least one of the following condition is reached:
the absolute difference between the gate emitter/source voltage and the flatband voltage V_{fb},h becomes superior to a predetermined limit, for example 4V or 5V; or
the gate current injection I_{g} duration tᵢₙⱼ exceeds a predetermined duration tₘₐₓ, the value of the predetermined duration tₘₐₓ could be dependent from a known capacity, C_{oxeq} (nominal or previously estimated or measured) of the semiconductor element 11.

In some embodiments, the two conditions are provided/configured such that the current injection is stopped as soon as one of the two conditions is reached. In various embodiments, only one of the two above conditions can be provided/configured, not the other one. In various embodiments, other conditions can be added. For example, the current injection can also be stopped when the derivative of the measured capacity Cₘₑₐₛ is stable.

In an example, for a current source I_{g} of 10 mA, a thin oxide capacitance C_{oxeq} of 20 nF, a gate voltage Vₑₑ during OFF state of −5V and an estimated flatband voltage V_{fb} between −2V and −3V, the maximum time tₘₐₓ is determined according to the following [Math. 8], here tₘₐₓ being equal to 6 μs.

$${t}_{max} \geq {C}_{oxeq} \cdot \frac{\vert {V}_{fb} - {V}_{ee} \vert}{{I}_{g}} \qquad [ Math . 8 ]$$

The updated value of the flatband voltage V_{fb,h+1} corresponds to the voltage V_{g} across the current source 44 measured at the same instant t of the current injection. In other words, operations d, e and f can be implemented for the same instant t.

The updated value of the flatband voltage V_{fb,h+1} is saved on any adapted support in a manner to construct an history of the flatband voltage V_{fb} values in function of time, along the operational life of the module 1.

In some embodiments, the above-described methods can form a loop: the same procedure is repeated several times after the first measurement that was stored in a memory in order to compare the flatband voltage evolution along time. In some embodiments, the method can be reiterated periodically, for example several hours/days.

In an embodiment shown on FIG. 5, the module 1 comprises (at least) two current sources: a first current source 54a and a second current source 54b. The current sources 54a, 54b are arranged in series with the same semiconductor element 11 to feed it. The first current source 54a and the second source 54b are positive. Each current source 54a, 54b is in parallel with a respective switch 56a, 56b. Such a structure is an example that enables to control the sign of the injected gate current I_{g}.

In some embodiments, the series of operations (a to f) are repeated. In such a manner, a plurality of flatband voltages V_{fb,h1}, V_{fb,h2}, . . . , V_{fb,hN} is obtained and stored. The flatband values enables to output a flatband evolution along time as a relative damage indicator of the gate oxide.

In some embodiments, when the flatband voltage V_{fb,h} is known and in the case of the flatband voltage V_{fb,h} is higher than the OFF-state voltage V_{EE}, a current source provides a positive gate current I_{g}, for example here from the first source 54a. Otherwise, in the case of the flatband voltage V_{fb} is lower than the OFF-state voltage V_{EE}, a current source provides a negative gate current I_{g}, for example here from the second source 54b. In other words, a negative gate current I_{g} is injected to a gate of the module 1 when the initial gate-emitter/source voltage is superior to the flatband voltage V_{fb,h}. In the case of a positive gate current, the current source 54a is used to increase the gate voltage until, at least, the flatband voltage V_{fb}. The first current source 54a is connected between the gate driver voltage source and the emitter/source of the semiconductor device. In the case of a negative gate current, the flatband voltage V_{fb} is lower than the OFF-state voltage V_{EE}, the current source 54b is used to decrease the gate voltage until the flatband voltage V_{fb}. The second current source 54b is placed between the emitter/source of the semiconductor element 11 and the gate driver voltage source.

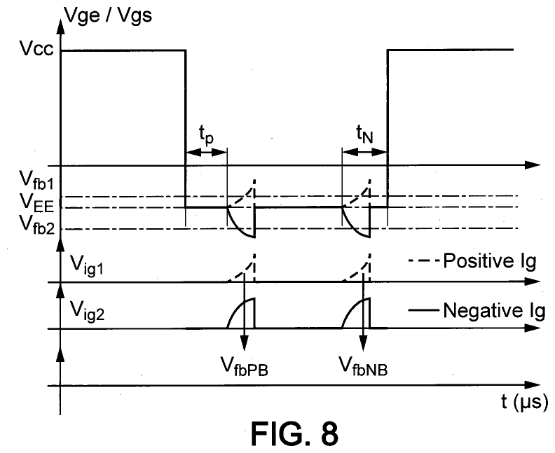

In the following, a methodology is described to decide the usage of the current source when a priori flatband voltage V_{fb} is not known. Firstly, a negative current source is used and the temporal derivative of V_{ig} is performed (calculated and stored) as above explained. The injection is performed until the voltage V_{ig} achieve a value close to the minimum allowed negative voltage of the power semiconductor element 11. For example, if the temporal derivative voltage (dV_{g}/dt) does not drop more than a predetermined relative value, for example 20%, the flatband voltage V_{f} is considered superior to the V_{EE} value and then a positive current source should be used in the next switching periods, as shown on FIG. 8. In such an example, the extracting of the flatband voltage V_{fb,h+1} from the said measured voltage V_{ig} across the current source can be made at the instant when the next triggering of a gate current is launched.

The circuit implementation of the two current sources is shown on FIG. 5. It details the exact placement of the current sources 54a and 54b and the measurement of the voltage V_{ig} used to estimate the flatband voltage V_{fb}.

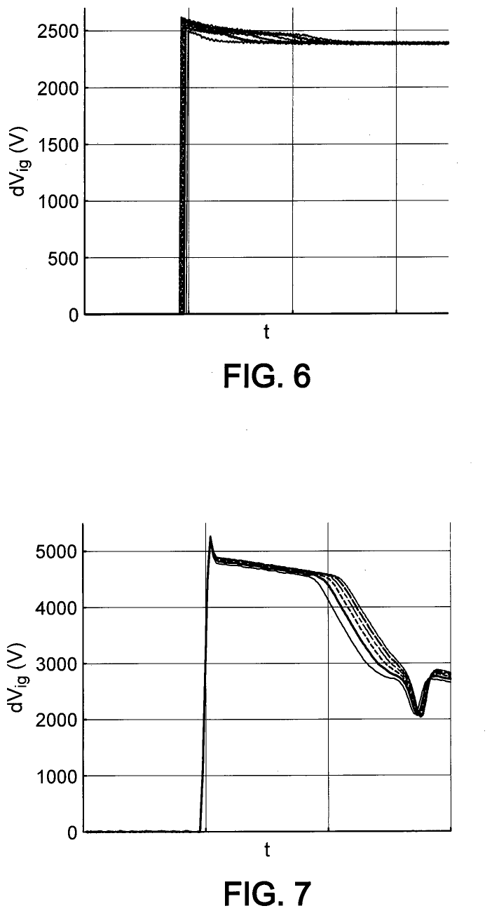

The obtained waveforms are shown on FIG. 6 and FIG. 7. In the examples of FIG. 6 and FIG. 7, the flatband voltage V_{fb} is equal to 4 Volts. In FIG. 6, the OFF-state voltage V_{EE} is equal to 5 Volts. In FIG. 7, the OFF-state voltage V_{EE} is equal to 0 Volt. On FIG. 8, the flatband voltage, represented by V_{fb1}, is higher than the V_{EE}. The current source I_{g1} and the measured voltage V_{ig1} are used to obtain the flatband voltage V_{fb1} from the semiconductor element 11. Otherwise, for the case when the flatband voltage V_{fb2} is lower than the V_{EE}, the current source I_{g2} and the measured voltage V_{ig2} are used to obtain the flatband voltage V_{fb2} from the semiconductor element 11.

In some embodiments, the flatband voltage V_{fb} is measured twice at the same switching period. This can be made in combination with the previous explanations. For this reason, it is also referred to FIG. 8. For example, a gate current I_{g} injection triggering can be made (into the gate):
after a time tₚ of the switching-off of the power semiconductor element 11, and the extraction (output) of a positive gate bias flatband voltage V_{fb,h+1}; and
a time to before the switching-on of the power semiconductor element 11, and the extraction (output) of a negative gate bias flatband voltage V_{fb,h+1}.

The respective flatband evolutions of said outputs can be used as a damage indicator of the gate oxide. The flatband voltage V_{fb} can be tracked just after the positive gate bias V_{fbPB} and at the end of the negative gate bias V_{fbNB} for any possible OFF-state voltage value V_{EE}. Furthermore, a classical two levels gate driver implementation is compatible with such measurements. Consequently, few changes on a gate driver are necessary to measure the BTI according to such an embodiment.

In practice, a timer can be used to count the time tₚ between the falling edged of the gate voltage and the current injection. A signal can be used to trigger the time tₙ. Or the previous switching pattern can be used to determine the total length of the OFF-state and the current injection is determined by triggering a timer that counts until the total previous OFF-state length minus the time tₙ.

The negative gate bias value V_{fbNB} can be acquired just before the turn-on, in such way, the monitoring can be made continually (for example within 10 μs between estimations) during the OFF-time and the last value before the turn-on is acquired. Advantageous, it only needs the internal gate control signals given that the gate signals are classically isolated from the main controller in known/existing modules.

In some embodiments, the flatband voltage V_{fb,h+1} is extracted from the said measured voltage V_{ig} across the current source at an instant when a gate current I_{g} injection is triggered in response to a condition on a second temporal derivative d²V_{g}/dt² of a measured voltage V_{g}. In other words, the second derivative of the current source voltage is used to trigger the measurement of the current injection time At that is the image of the flatband voltage V_{fb} according to the following [Math. 9].

$${V}_{fb} = {Φ}_{MS} - \frac{{I}_{g} \cdot Δ t}{{C}_{ox}} \qquad [ Math . 9 ]$$

Φ_{MS} is the work function difference between the gate metal material and the semiconductor material.

To use a fast sampling rate ADCs (“Analogic-to-Digital Converter”) is possible but not necessary to detect the derivative of the equivalent capacitor: a simple analogue circuit can be used to trigger a fast counter. A higher current source value with a smaller measurement time is possible.

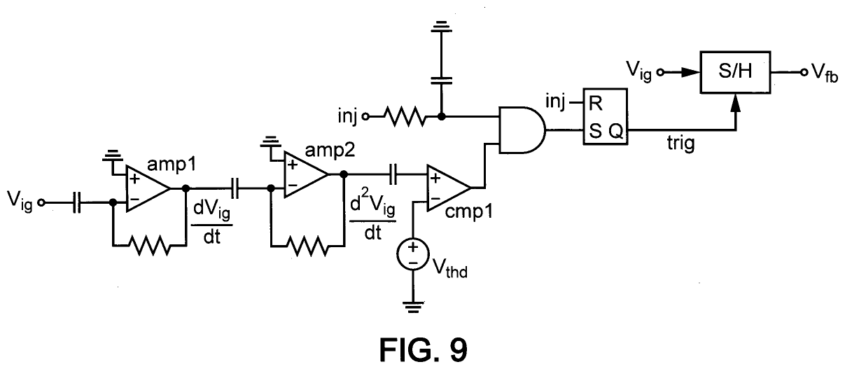

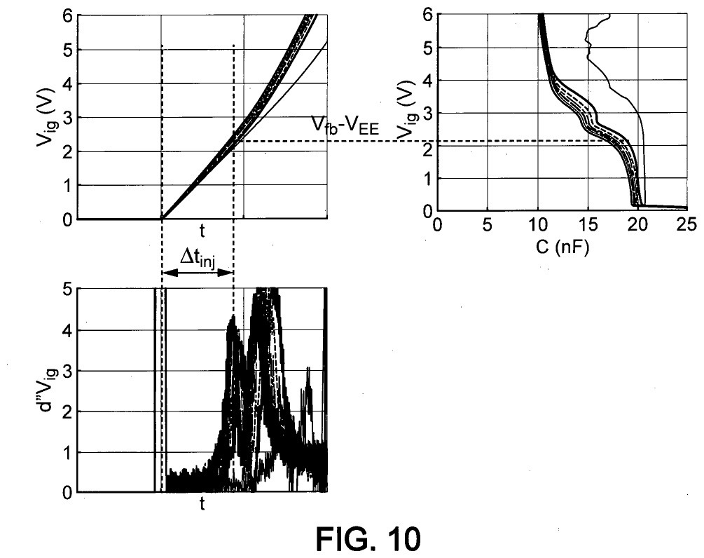

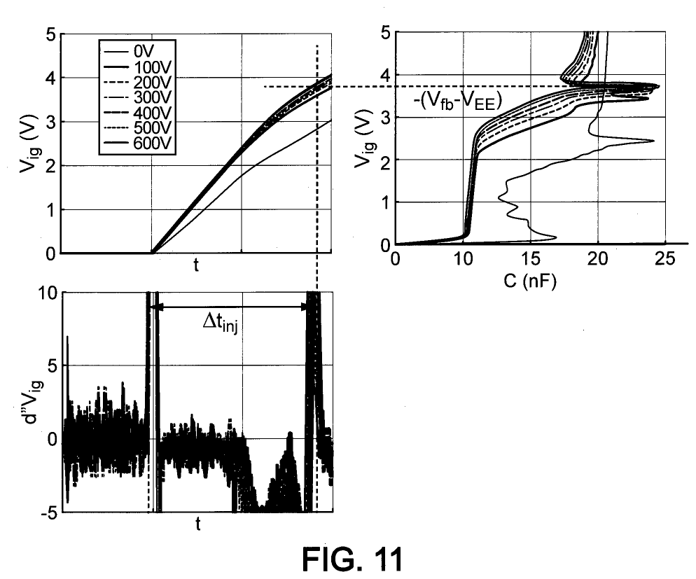

Referring to FIG. 6 and FIG. 7, the first peak of the second V_{ig} derivative represents the instant when the current is injected on the gate. The second peak is used to trigger the V_{ig} measurement through for example a “sample and hold”. For the application, the second derivative is compared to a threshold value V_{thd} equals to 2 Volts when a gain of 1e-6 is used. An example of a circuitry to use the second derivative to generate a trigger is presented in FIG. 9. FIG. 10 shows graphically the methodology when a positive current source is used. FIG. 11 shows graphically the methodology when a negative current source is used.

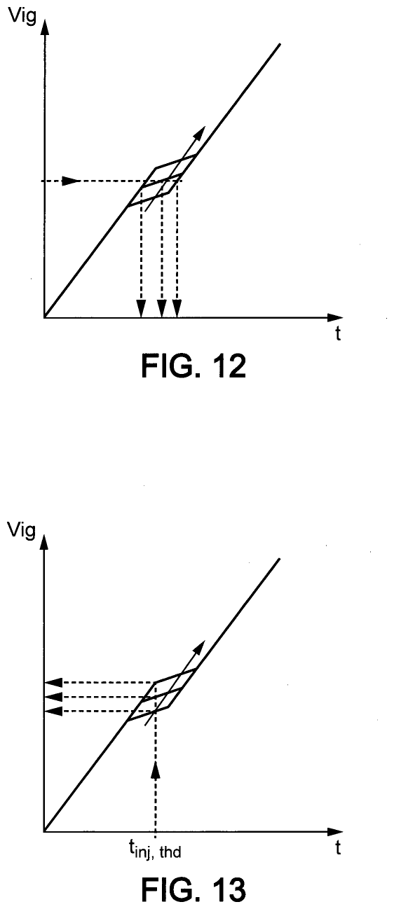

In some embodiments, the measurement of the voltage V_{g} across the current source and the corresponding extraction of a flatband voltage V_{fb,h+1} is made in function of:
a duration of the injection Δtᵢₙⱼ after the instant t when a current source voltage V_{ig} reaches a threshold value V_{thd} (see FIG. 12); or
a current source voltage V_{ig} after a predetermined duration t_{inj,thd} of the gate current I_{g} injection triggering (see FIG. 13).

In both cases, the measurement (a duration or a voltage) is the image of the flatband voltage V_{fb}. Doing this, a low-noise and a low-cost estimate of a parameter linked to the flatband voltage is established. In the case of an extraction based on a voltage measurement, no ADC is necessary. In the case of an extraction based on a time, no hardware is required to set the trigger.

In case of a current source threshold voltage value V_{thd} is used to trigger the measurement of the injection time Δtᵢₙⱼ, the voltage value V_{thd} is defined to be slightly above, respectively below, the expected increase, respectively decrease, of the flatband voltage drift. The injection time Δtᵢₙⱼ value is measured and the flatband voltage V_{fb} is then estimated by the following equation [Math. 10].

$${V}_{fb} = {Φ}_{MS} - \frac{{I}_{g} \cdot Δ {t}_{inj}}{{C}_{ox}} \qquad [ Math . 10 ]$$

In case of a current injection threshold time t_{inj,thd} is used to trigger the measurement of the current source voltage V_{ig}, the time delay value is defined to be slightly above, respectively below, the expected increase, respectively decrease, of the time to reach the flatband voltage V_{fb}.

In some embodiments, a bus voltage measurement is made before the flatband voltage V_{fb} extraction. In some embodiments, a measurement of the duration of the ON state and/or of the duration of the OFF state is made before the flatband voltage V_{fb} extraction. Thus, the evolution of the gate oxide deterioration can be observed as a function of specific operating parameters, such the bus voltage, the time of positive gate bias; the time of the negative gate bias; the switching frequency and/or the junction temperature.

### INDUSTRIAL APPLICABILITY

In some know methods, measuring a small signal capacitance using a C-V meter applies a DC bias voltage V_{g} and a small sinusoidal signal to the MOS capacitor, and there is a measure of the capacitive current with an AC ammeter. In the above embodiments, there is an on-line flatband voltage V_{fb} measurement during a Pulse-Width Modulation (PWM) field application. This method is applicable for any Metal Oxide Semiconductor (MOS) and Metal-Insulator-Semiconductor (MIS) type, for example MOSFETs and IGBTs transistors. The Bias Temperature Instability (BTI) is estimated in the insulated gate power semiconductor elements. The BTI is measured using the flatband indicator with an in-situ circuit measurement associated to the gate driver control of the power semiconductor elements during the operation of the power semiconductor in a field application.

The deterioration of the gate oxide can be detected during the power semiconductor operation within few microseconds after the end of the positive gate voltage bias and in the end of the negative gate voltage bias by the measurement of the flatband voltage V_{fb}. Thus, the gate charge trapping evolution and the gate charge trapping hysteresis can be evaluated along the lifetime of the power semiconductor elements in the field application. Furthermore, the current state of the semiconductor module is not changed during the measurements and does not prevent the normal operation of the module: it is transparent to the users. Finally, the reliability of the power semiconductor module is increased and guaranteed by the on-line measurements.

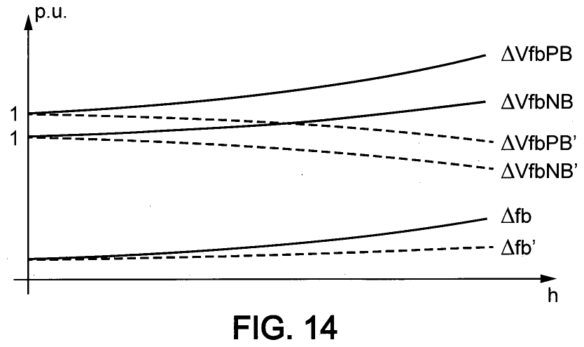

Caused by the positive/negative temperature bias instability (PBTI/NBTI), the evolution of the flatband voltage V_{fb} that is representative of the evolution of the threshold voltage Vₜₕ can be monitored along the lifetime of the power semiconductor module as shown in FIG. 14.

This disclosure is not limited to the methods, modules, circuitries and computer software described here, which are only examples. The invention encompasses every alternative that a person skilled in the art would envisage when reading this text.

### REFERENCE SIGNS LIST

1: module
11: semiconductor element
12: control circuitry
21: curve for an aging of 10 hours
22: curve for an aging of 100 hours
23: curve for an aging of 200 hours
24: curve for an aging of 300 hours
31: curve before aging
32: curve after aging at 250 μs
41: voltage source
43: control unit
44: current source
46: switch
54a: first current source
54b: second current source
56a: first switch
56b: second switch
CTRL1: control signal
CTRL2: control signal.

1. A measurement method of a flatband voltage of a power semiconductor module comprising at least one semiconductor element among a Metal-Oxide-Semiconductor element and a Metal-Insulator Semiconductor element during operational service, said method comprising:
a. applying a bias voltage to said module such that said module switches from an off-state to an on-state, or from an on-state to an off-state;
b. triggering a gate current I_{g} injection from a current source to a gate of the module when an initial gate-emitter/source voltage is equal to a flatband voltage V_{fb,h} of the module within +/−5V;
c. measuring the voltage V_{ig} across the current source;
d. extracting of a flatband voltage V_{fb,h+1} from the said measured voltage V_{ig} across the current source
e. stopping said gate current I_{g} injection
when the absolute difference between the gate emitter/source voltage and the flatband voltage V_{fb,h} becomes superior to a predefined limit; or
when the gate current I_{g} injection duration tᵢₙⱼ exceeds a predetermined duration tₘₐₓ;
f. saving the extracted flatband voltage V_{fb,h+1} value.

2. The method according to claim 1, further comprising:
measuring a capacity Cₘₑₐₛ of the at least one semiconductor element, and wherein the extracted flatband voltage V_{fb,h+1} is the measured voltage V_{ig} across the current source triggered when a transition between a constant Cₘₑₐₛ to a variable Cₘₑₐₛ is detected from the capacity measurement.

3. The method according to claim 1, wherein the sign of the injected gate current I_{g} depends on the ON/OFF state of the semiconductor element.

4. The method according to claim 3, wherein
the injected gate current I_{g} is negative
the gate current I_{g} injection is stopped when the measured voltage V_{ig} achieves a predetermined negative voltage,
the temporal derivative voltage dV_{ig}/dt is calculated and stored in such a way that it can be used as an input parameter to reiterate the method.

5. The method according to claim 4, wherein
if the calculated temporal derivative voltage dV_{ig}/dt does not drop more than a predetermined relative value, the method is then reiterated with a positive injected gate current I_{g}.

6. The method according to claim 1, wherein the gate current I_{g} injection triggering is made:
after a time tₚ of the switching-off of the semiconductor element, and the extraction of a positive gate bias flatband voltage V_{fb,h+1}; and/or
a time tₙ before the switching-on of the semiconductor element.

7. The method according to claim 1, wherein the flatband voltage V_{fb,h+1} is extracted from the said measured voltage V_{ig} across the current source at an instant when a gate current I_{g} injection is triggered in response to a condition on a second temporal derivative d²V_{ig}/dt² of a measured voltage V_{ig}.

8. The method according to claim 1, further comprising:
a bus voltage measurement before the flatband voltage V_{fb,h+1} extraction, and
a measurement of the duration of the ON state and/or of the duration of the OFF state before the flatband voltage V_{fb,h+1} extraction.

9. The method according to claim 1, wherein the series of operations is reiterated at least one time such that to output a flatband evolution along time.

10. A power semiconductor module comprising a single Metal-Oxide-Semiconductor or a single Metal-Insulator-Semiconductor element or a set of Metal-Oxide-Semiconductor elements or a set of Metal-Insulator-Semiconductor elements or a combination of Metal-Oxide-Semiconductor elements and Metal-Insulator-Semiconductor elements, said module further comprising circuitry adapted to measure a voltage V_{ig} across a current source and being arranged to implement the method according to claim 1.

11. Computer software comprising instructions to implement the method according to claim 1 when the software is executed by a processor.

12. Computer-readable non-transient recording medium on which a software is registered to implement the method according to claim 1 when the software is executed by a processor.
